(19) United States
(12) Patent Application Publication
(10) Pub. No.: US 2024/0088846 A1
(43) Pub. Date: Mar. 14, 2024

(54) AMPLIFIER ASSEMBLY WITH ENHANCED TEMPERATURE COMPENSATED BEHAVIOR, FRONT END MODULE, AND MOBILE DEVICE INCLUDING THE SAME

(71) Applicant: SKYWORKS SOLUTIONS, INC., Irvine, CA (US)

(72) Inventors: Florinel G. Balteanu, Irvine, CA (US); Sruthi Venimadhavan, Irvine, CA (US); Kiran Tej Thoomu, Irvine, CA (US); Yunyoung Choi, Irvine, CA (US)

(21) Appl. No.: 18/243,951

(22) Filed: Sep. 8, 2023

Related U.S. Application Data
(60) Provisional application No. 63/406,490, filed on Sep. 14, 2022.

(51) Int. Cl. H03F 3/24; H03F 1/30

(52) U.S. Cl. CPC H03F 3/245; H03F 1/301; H03F 2200/294; H03F 2200/451; H03F 2200/468

(57) ABSTRACT

An amplifier assembly including an amplification circuit configured to amplify a radio frequency signal when biased by a biasing signal, a temperature sensing circuit configured to sense a temperature at a certain position of the amplification circuit, and at least one biasing circuit configured to generate the biasing signal with a temperature gradient dependent on the sensed temperature. The biasing circuit includes a first transistor biased by a reference voltage and a second transistor biased by an input voltage proportional to the sensed temperature, the first transistor and the second transistor connected to a current source via respective slope resistors such to induce current proportional to the sensed temperature. The biasing circuit further includes a third transistor configured to output the biasing signal based on a control current flowing through the second transistor, the temperature gradient of the biasing signal being determined by the respective slope resistors.

### CROSS-REFERENCE TO RELATED APPLICATIONS

This application claims priority under 35 U.S.C. § 119(e) to U.S. Provisional Patent Application Ser. No. 63/406,490, titled “AMPLIFIER ASSEMBLY WITH ENHANCED TEMPERATURE COMPENSATED BEHAVIOR, FRONT END MODULE, AND MOBILE DEVICE INCLUDING THE SAME,” filed Sep. 14, 2022, the entire content of which is incorporated herein by reference in its entirety for all purposes.

### BACKGROUND

### Field

Embodiments of the present disclosure relate to electronic systems, and in particular, to power amplifiers (PAs) or low-noise amplifiers (LNA) for use in radio frequency (RF) electronics.

### Description of the Related Technology

Power amplifiers are used in radio frequency (RF) communication systems to amplify RF signals for transmission via antennas. Low-noise amplifier (LNAs) are used in radio frequency communication systems to amplify RF signals for reception via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4 is a schematic diagram of one embodiment of a transmit system for transmitting radio frequency (RF) signals from a mobile device.

FIG. 5 is a schematic diagram of a front end system according to one embodiment.

FIG. 6 is a schematic diagram of a front end system according to another embodiment.

FIG. 7 is a schematic diagram of one embodiment of an RF system.

FIG. 8A shows a SOI structure according to an embodiment.

FIG. 8B shows thermal characteristics depending on locations of the SOI according to an embodiment.

FIG. 9A illustrate schematic diagrams of circuits for setting signals (voltage/current) dependent on temperature according to prior art.

FIG. 9B illustrate schematic diagrams of circuits for setting signals (voltage/current) dependent on temperature according to prior art.

FIG. 10 is a schematic diagram of an amplifier assembly according to aspects of the present disclosure.

FIG. 11 is a schematic diagram of the biasing circuit according to an embodiment of the present disclosure.

FIG. 12 is a schematic diagram of the biasing circuit according to an embodiment of the present disclosure.

FIG. 13 is a schematic diagram of a plurality of the biasing circuits according to an embodiment of the present disclosure.

FIG. 14 is a schematic diagram of an amplifier assembly including a plurality of biasing circuits, a multiplexer and a trimming circuit according to an embodiment of the present disclosure.

FIG. 15 is a schematic diagram of analog multiplexer according to an embodiment of the present disclosure.

FIG. 16 is a schematic diagram of temperature sensing circuit according to an embodiment of the present disclosure.

FIG. 17 is a schematic diagram of temperature sensing circuit including a calibration circuit according to an embodiment of the present disclosure.

FIG. 18A is a schematic diagram of one embodiment of a packaged module.

FIG. 18B is a schematic diagram of a cross-section of the packaged module of FIG. 19A taken along the lines 19A-19B.

FIG. 19 is a schematic diagram of one embodiment of a phone board.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

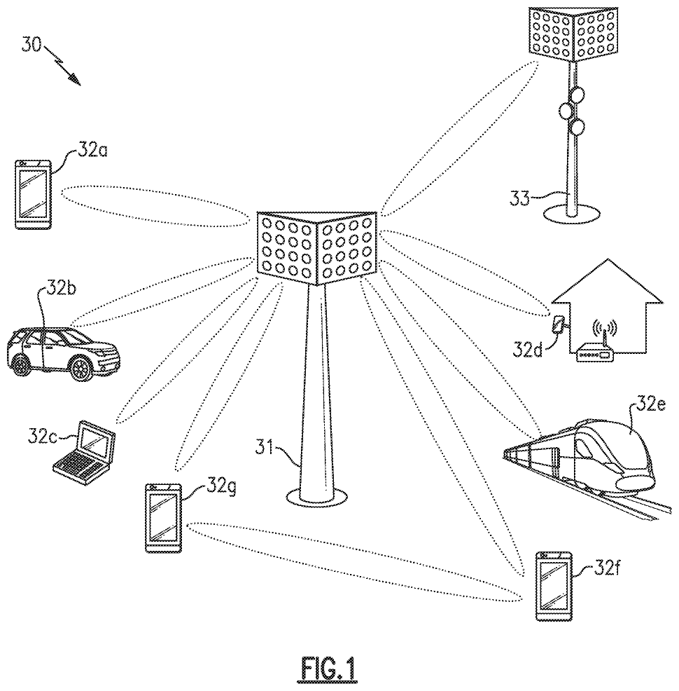

FIG. 1 is a schematic diagram of one example of a communication network 30. The communication network 30 includes a macro cell base station 31, a small cell base station 33, and various examples of user equipment (UE), including a first mobile device 32a, a wireless-connected car 32b, a laptop 32c, a stationary wireless device 32d, a wireless-connected train 32e, a second mobile device 32f, and a third mobile device 32g.

Although specific examples of base stations and user equipment are illustrated in FIG. 1, a communication network can include base stations and user equipment of a wide variety of types and/or numbers.

For instance, in the example shown, the communication network 30 includes the macro cell base station 31 and the small cell base station 33. The small cell base station 33 can operate with relatively lower power, shorter range, and/or with fewer concurrent users relative to the macro cell base station 31. The small cell base station 33 can also be referred to as a femtocell, a picocell, or a microcell. Although the communication network 30 is illustrated as including two base stations, the communication network 30 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described herein.

The illustrated communication network 30 of FIG. 1 supports communications using a variety of cellular technologies, including, for example, 4G LTE and 5G NR. In certain implementations, the communication network 30 is further adapted to provide a wireless local area network (WLAN), such as WiFi. Although various examples of communication technologies have been provided, the communication network 30 can be adapted to support a wide variety of communication technologies.

Various communication links of the communication network 30 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 30 can be implemented to support self-fronthaul and/or self-backhaul (for instance, as between mobile device 32g and mobile device 32f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 30 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 30 of FIG. 1 can be used to support a wide variety of advanced communication features, including, but not limited to, eMBB, uRLLC, and/or mMTC.

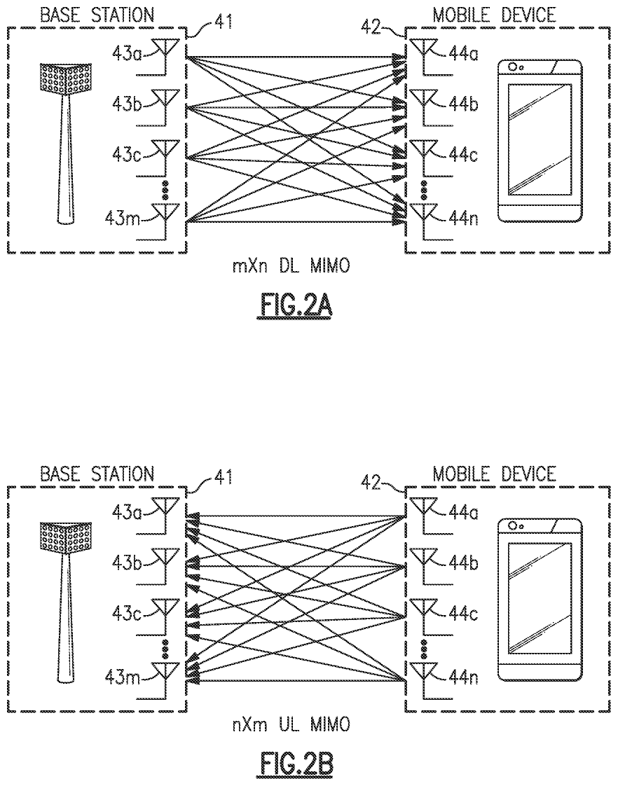

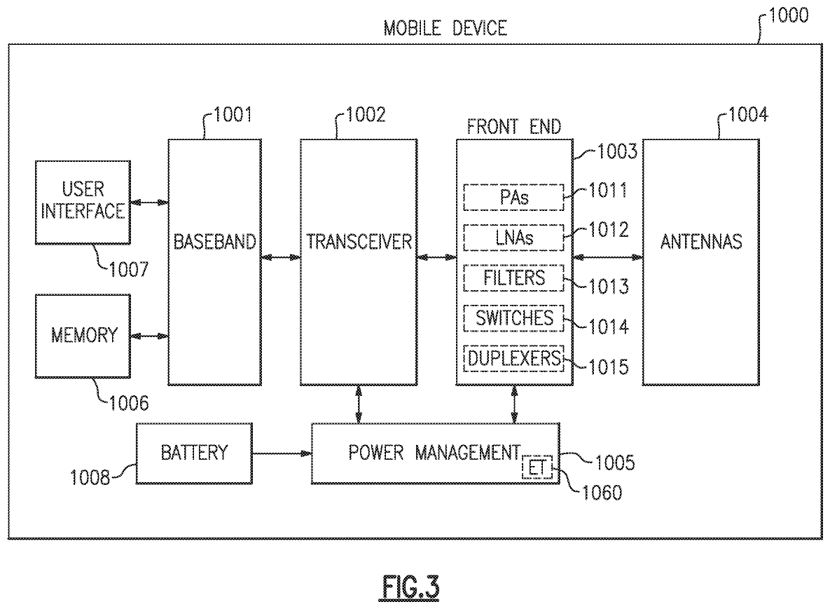

FIG. 2A is a schematic diagram of one example of a downlink channel using multi-input and multi-output (MIMO) communications. FIG. 2B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 2A, downlink MIMO communications are provided by transmitting using M antennas 43a, 43b, 43c, . . . 43m of the base station 41 and receiving using N antennas 44a, 44b, 44c, . . . 44 n of the mobile device 42. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3 is a schematic diagram of one example of a mobile device 1000. The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 3 as the transceiver 1002. In one example, separate components (for instance, separate circuits or dies) can be provided for handling certain types of RF signals.

The front end system 1003 aids in conditioning signals transmitted to and/or received from the antennas 1004. In the illustrated embodiment, the front end system 1003 includes power amplifiers (PAs) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters can be controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 to facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage from the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

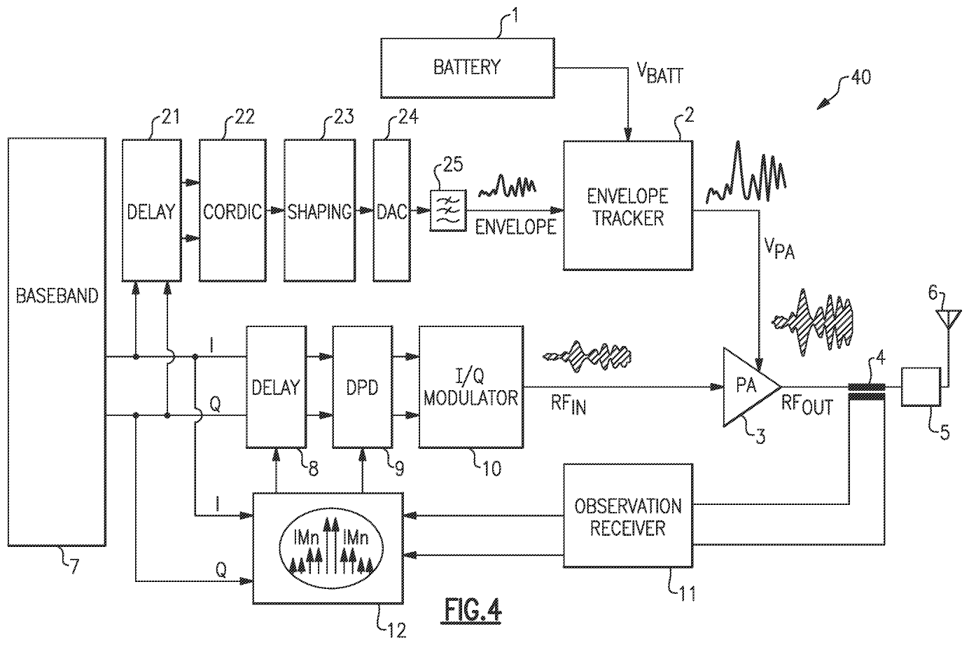

FIG. 4 is a schematic diagram of one embodiment of a transmit system for transmitting RF signals from a mobile device. The transmit system 40 includes a battery 1, an envelope tracker 2, a power amplifier 3, a directional coupler 4, a duplexing and switching circuit 5, an antenna 6, a baseband processor 7, a signal delay circuit 8, a digital pre-distortion (DPD) circuit 9, an I/Q modulator 10, an observation receiver 11, an intermodulation detection circuit 12, an envelope delay circuit 21, a coordinate rotation digital computation (CORDIC) circuit 22, a shaping circuit 23, a digital-to-analog converter 24, and a reconstruction filter 25.

The transmit system 40 of FIG. 4 illustrates one example of an RF communication system that can include power amplifier(s) implemented in accordance with one or more features of the present disclosure. However, the teachings herein are applicable to RF communication systems implemented in a wide variety of ways.

The baseband processor 7 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/Q modulator 10 in a digital format. The baseband processor 7 can be any suitable processor configured to process a baseband signal. For instance, the baseband processor 7 can include a digital signal processor, a microprocessor, a programmable core, or any combination thereof.

The signal delay circuit 8 provides adjustable delay to the I and Q signals to aid in controlling relative alignment between the envelope signal and the RF signal RF_{IN}. The amount of delay provided by the signal delay circuit 8 is controlled based on amount of intermodulation detected by the intermodulation detection circuit 12.

The DPD circuit 9 operates to provide digital shaping to the delayed I and Q signals from the signal delay circuit 8 to generate digitally pre-distorted I and Q signals. In the illustrated embodiment, the DPD provided by the DPD circuit 9 is controlled based on amount of intermodulation detected by the intermodulation detection circuit 12. The DPD circuit 9 serves to reduce a distortion of the power amplifier 3 and/or to increase the efficiency of the power amplifier 3. The DPD circuit 9 is configured to provide the power amplifier 3 with a bias signal, which is controlled by a loop through the baseband processor 7. Therefore, the power amplifier 3 is powered by a supply voltage and biased by a bias signal.

The I/Q modulator 10 receives the digitally pre-distorted I and Q signals, which are processed to generate an RF signal RF_{IN}. For example, the I/Q modulator 10 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 3. In certain implementations, the I/Q modulator 10 can include one or more filters configured to filter frequency content of signals processed therein.

The envelope delay circuit 21 delays the I and Q signals from the baseband processor 7. Additionally, the CORDIC circuit 22 processes the delayed I and Q signals to generate a digital envelope signal representing an envelope of the RF signal RF_{IN}. Although FIG. 4 illustrates an implementation using the CORDIC circuit 22, an envelope signal can be obtained in other ways.

The shaping circuit 23 operates to shape the digital envelope signal to enhance the performance of the transmit system 30. In certain implementations, the shaping circuit 23 includes a shaping table that maps each level of the digital envelope signal to a corresponding shaped envelope signal level. Envelope shaping can aid in controlling linearity, distortion, and/or efficiency of the power amplifier 3.

In the illustrated embodiment, the shaped envelope signal is a digital signal that is converted by the DAC 24 to an analog envelope signal. Additionally, the analog envelope signal is filtered by the reconstruction filter 25 to generate an envelope signal suitable for use by the envelope tracker 2. In certain implementations, the reconstruction filter 25 includes a low pass filter.

With continuing reference to FIG. 4, the envelope tracker 2 receives the envelope signal from the reconstruction filter 25 and a battery voltage V_{BATT} from the battery 1, and uses the envelope signal to generate a power amplifier supply voltage V_{PA} for the power amplifier 3 that changes in relation to the envelope of the RF signal RF_{IN}. The power amplifier 3 receives the RF signal RF_{IN} from the I/Q modulator 10, and provides an amplified RF signal RF_{OUT} to the antenna 6 through the duplexing and switching circuit 5, in this example.

The directional coupler 4 is positioned between the output of the power amplifier 3 and the input of the duplexing and switching circuit 5, thereby allowing a measurement of output power of the power amplifier 3 that does not include insertion loss of the duplexing and switching circuit 5. The sensed output signal from the directional coupler 4 is provided to the observation receiver 11, which can include mixers for down converting I and Q signal components of the sensed output signal, and DACs for generating I and Q observation signals from the down-converted signals.

The intermodulation detection circuit 12 determines an intermodulation product between the I and Q observation signals and the I and Q signals from the baseband processor 7. Additionally, the intermodulation detection circuit 12 controls the DPD provided by the DPD circuit 9 and/or a delay of the signal delay circuit 8 to control relative alignment between the envelope signal and the RF signal RF_{IN}.

By including a feedback path from the output of the power amplifier 3 and baseband, the I and Q signals can be dynamically adjusted to optimize the operation of the transmit system 30. For example, configuring the transmit system 30 in this manner can aid in providing power control, compensating for transmitter impairments, and/or in performing DPD.

Although illustrated as a single stage, the power amplifier 3 can include one or more stages. Furthermore, RF communication systems such as mobile devices can include multiple power amplifiers. In such implementations, separate envelope trackers can be provided for different power amplifiers and/or one or more shared envelope trackers can be used.

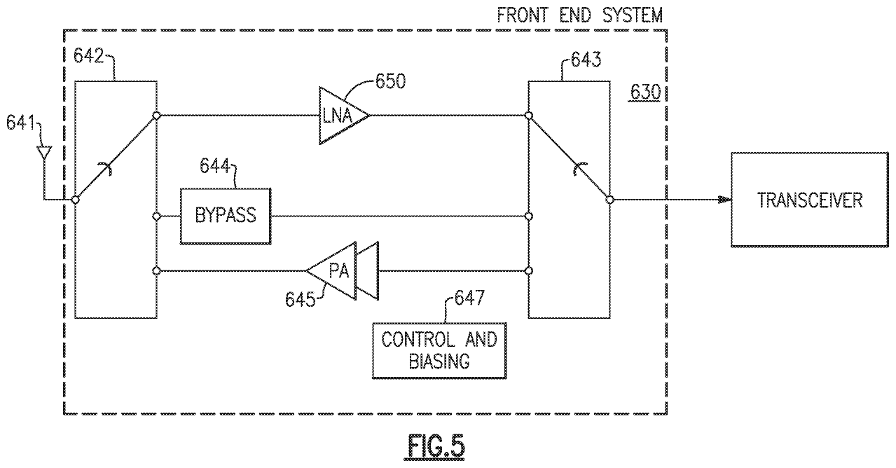

FIG. 5 is a schematic diagram of a front end system 630 according to one embodiment.

The RF front end system 630 is configured to receive RF signals from an antenna 641 and to transmit RF signals by way of the antenna 641. The illustrated front end system 630 includes a first multi-throw switch 642, a second multi-throw switch 643, a receive signal path that includes an LNA 650, a bypass signal path that includes a bypass network 644, and a transmit signal path that includes a power amplifier 645. The bypass network 644 can include any suitable network for matching and/or bypassing the receive signal path and the transmit signal path. The bypass network 644 can be implemented by a passive impedance network or by a conductive trace or wire. The power amplifier 645 can be implemented in a wide variety of ways.

The first multi-throw switch 642 can selectively connect a particular signal path to the antenna 641. The first multi-throw switch 642 can electrically connect the receive signal path to the antenna 641 in a first state, electrically connect the bypass signal path to the antenna 641 in a second state, and electrically connect the transmit signal path to the antenna 641 in a third state. When the first multi-throw switch 642 selects the receive signal path including the LNA 650, a feedback signal is used to control an impedance of the switch 642 between the antenna 641 and the input to the LNA 650.

The second multi-throw switch 643 can selectively connect a particular signal path to an input/output port of the front end system 630, in which the particular signal path is the same signal path electrically connected to the antenna 641 by way of the first multi-throw switch 642. Accordingly, the second multi-throw switch 643 together with the first multi-throw switch 642 can selectively connect a particular signal path between the antenna 641 and the input/output port of the front end system 630.

The control and biasing circuit 647 can be used to control and bias circuitry of the RF front end system 630, including, but not limited to, the power amplifier 645, an overload protection circuit (not shown), the LNA 650, and/or the multi-throw switches 642/643.

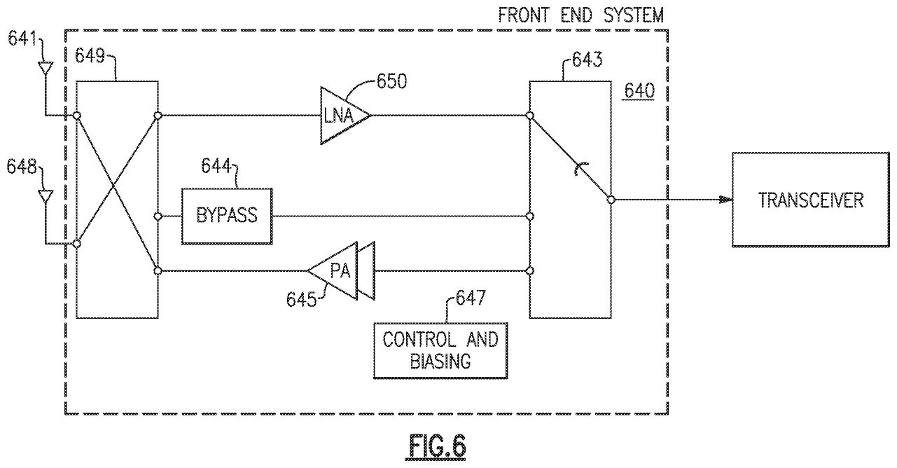

FIG. 6 is a schematic diagram of a front end system 640 according to another embodiment.

The RF front end system 640 of FIG. 6 is similar to the RF front end system 630 of FIG. 5, except that the first multi-throw switch 649 is configured to selectively connect a particular signal path to either a first antenna 641 or a second antenna 648. The multi-throw switch 649 can be a multi-throw, multi-pole switch.

The front end systems of FIGS. 5 and/or 6 can be implemented in a packaged module. Such packaged modules can include relatively low cost laminate-based front end modules that combine low noise amplifiers with power amplifiers and/or switch functions. Some such packaged modules can be multi-chip modules. In certain implementations, some or all of the illustrated components in any of the front end systems in FIGS. 5 and/or 6 can be embodied on a single integrated circuit or die. Such a die can be manufactured using any suitable process technology. As one example, the die can be a semiconductor-on-insulator die, such as a silicon-on-insulator (SOI) die. According to some implementations, one or more antennas can be integrated with any of the front end systems discussed herein.

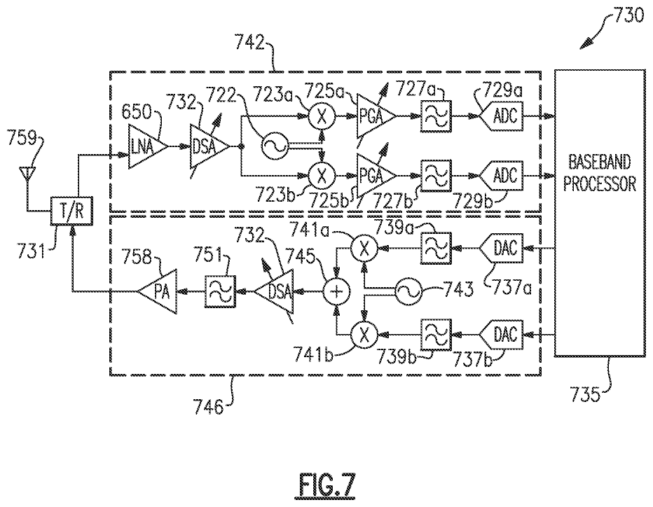

FIG. 7 is a schematic diagram of one embodiment of an RF system 730. The RF system 730 includes a baseband processor 735, a receive path 742, a transmit path 746, a T/R switch 731, and an antenna 759. The RF system 730 illustrates one example of a communications system architecture that can include one or more LNAs implemented in accordance with the teachings herein.

The RF system 730 can be used for transmitting and/or receiving RF signals using a variety of communication standards, including, for example, Global System for Mobile Communications (GSM), Code Division Multiple Access (CDMA), wideband CDMA (W-CDMA), Long Term Evolution (LTE), Advanced LTE, 3G (including 3GPP), 4G, 5G, Enhanced Data Rates for GSM Evolution (EDGE), wireless local loop (WLL), and/or Worldwide Interoperability for Microwave Access (WiMax), as well as other proprietary and non-proprietary communications standards.

The transmit path 746 and the receive path 742 can be used for transmitting and receiving signals over the antenna 759. Although one implementation of the RF system 730 is illustrated in FIG. 7, the RF system 730 can be modified in any suitable manner. For example, the RF System 730 can be modified to include additional transmit paths, receive paths, and/or antennas.

In the illustrated configuration, the receive path 742 includes a low noise amplifier (LNA) 650, a Digital Switched Attenuator (DSA) 732, a local oscillator 722, a first mixer 723 a, a second mixer 723 b, a first programmable gain amplifier (PGA) 725 a, a second PGA 725 b, a first filter 727 a, a second filter 727 b, a first analog-to-digital converter (ADC) 729 a, and a second ADC 729 b. Although one implementation of a receive path is illustrated in FIG. 7, a receive path can include more or fewer components and/or a different arrangement of components.

An RF signal can be received on the antenna 759 and provided to the receive path 742 using the T/R switch 731. For example, the T/R switch 731 can be controlled to electrically couple the antenna 759 to an input of the LNA 650, thereby providing the received RF signal to the LNA's input. The LNA 650 provides low noise amplification such that the LNA 650 amplifies the received RF signal while adding or introducing a relatively small amount of noise.

As shown in FIG. 7, the amplified RF signal generated by the LNA 650 is provided to a Digital Switched Attenuator DSA 732. In the illustrated embodiment, an amount of attenuation provided by the DSA 732 is digitally-controllable, and can be set to achieve a desired signal power level.

The first and second mixers 723 a, 723 b receive first and second local oscillator clock signals, respectively, from the local oscillator 722. The first and second local oscillator clock signals can have about the same frequency and a phase difference equal to about a quarter of a period, or about 90°. The first and second mixers 723 a, 723 b down-convert the output of the DSA 732 using the first and second local oscillator clock signals, respectively, thereby generating first and second demodulated signals. The first and second demodulated signals can have a relative phase difference of about a quarter of a period, or about 90°, and can correspond to an in-phase (I) receive signal and a quadrature-phase (Q) signal, respectively. In certain implementations, one of the first or second oscillator clock signals is generated by phase shifting from the other.

The first and second local oscillator clock signals can have a frequency selected to achieve a desired intermediate frequency and/or baseband frequency for the first and second demodulated signals. For example, multiplying the output of the DSA 732 by a sinusoidal signal from the local oscillator 722 can produce a mixed signal having a frequency content centered about the sum and difference frequencies of the carrier frequency of the DSA output signal and the oscillation frequency of the local oscillator 722.

In the illustrated configuration, the first and second demodulated signals are amplified using the first and second programmable gain amplifiers 725 a, 725 b, respectively. To aid in reducing output noise, the outputs of the first and second programmable gain amplifiers 725 a, 725 b can be filtered using the first and second filters 727 a, 727 b, which can be any suitable filter, including, for example, low pass, band pass, or high pass filters. The outputs of the first and second filters 727 a, 727 b can be provided to the first and second ADCs 729 a, 729 b, respectively. The first and second ADCs 729 a, 729 b can have any suitable resolution. In the illustrated configuration, the outputs of the first and second ADCs 729 a, 729 b are provided to the baseband processor 735 for processing.

The baseband processor 735 can be implemented in a variety of ways. For instance, the baseband processor 735 can include a digital signal processor, a microprocessor, a programmable core, the like, or any combination thereof. Moreover, in some implementations, two or more baseband processors can be included in the RF system 730.

As shown in FIG. 7, the transmit path 746 receives data from the baseband processor 735 and is used to transmit RF signals via the antenna 759. The transmit path 746 and the receive path 742 both operate using the antenna 759, and access to the antenna 759 is controlled using the T/R switch 731. The illustrated transmit path 746 includes first and second digital-to-analog converters (DACs) 737 a, 737 b, first and second filters 739 a, 739 b, first and second mixers 741 a, 741 b, a local oscillator 743, a combiner 745, a DSA 732, an output filter 751, and a power amplifier 758. Although one implementation of a transmit path is illustrated in FIG. 7, a transmit path can include more or fewer components and/or a different arrangement of components.

The baseband processor 735 can output a digital in-phase (I) signal and a digital quadrature-phase (Q) signal, which can be separately processed until they are combined using the combiner 745. The first DAC 737 a converts the digital I signal into an analog I signal, and the second DAC 737 b converts the digital Q signal into an analog Q signal. The first and second DACs 737 a, 737 b can have any suitable precision. The analog I signal and the analog Q signal can be filtered using the first and second filters 739 a, 739 b, respectively. The outputs of the first and second filters 739 a, 739 b can be upconverted using the first and second mixers 741 a, 741 b, respectively. For example, the first mixer 741 a is used to upconvert the output of the first filter 739 a based on an oscillation frequency of the local oscillator 743, and the second mixer 741 b is used to upconvert the output of the second filter 739 b based on the oscillation frequency of the local oscillator 743.

The combiner 745 combines the outputs of the first and second mixers 741 a, 741 b to generate a combined RF signal. The combined RF signal is provided to an input of the DSA 732, which is used to control a signal power level of the combined RF signal.

The output of the DSA 732 can be filtered using the output filter 751, which can be, for example, a low pass, band pass, or high pass filter configured to remove noise and/or unwanted frequency components from the signal. The output of the output filter 751 can be amplified by a power amplifier 758. In some implementations, the power amplifier 758 includes a plurality of stages cascaded to achieve a target gain. The power amplifier 758 can provide an amplified RF signal to the antenna 759 through the T/R switch 731.

Recently, the control for smartphones in response to increase of temperature has drawn a huge interest in the industries. If the control in response to temperature change does not work properly, the device can be degraded in the performance, and can even be destroyed.

Depending on the requirements, a plurality of power amplifiers may need to be placed on a same die. In this case, however, the SOI (silicon-on-insulator), which is used extensively in RF front end modules, has some challenges due to non-uniform heat transfer. Particularly, for mmWave power amplifiers, the degradation of RF performance is even more severe.

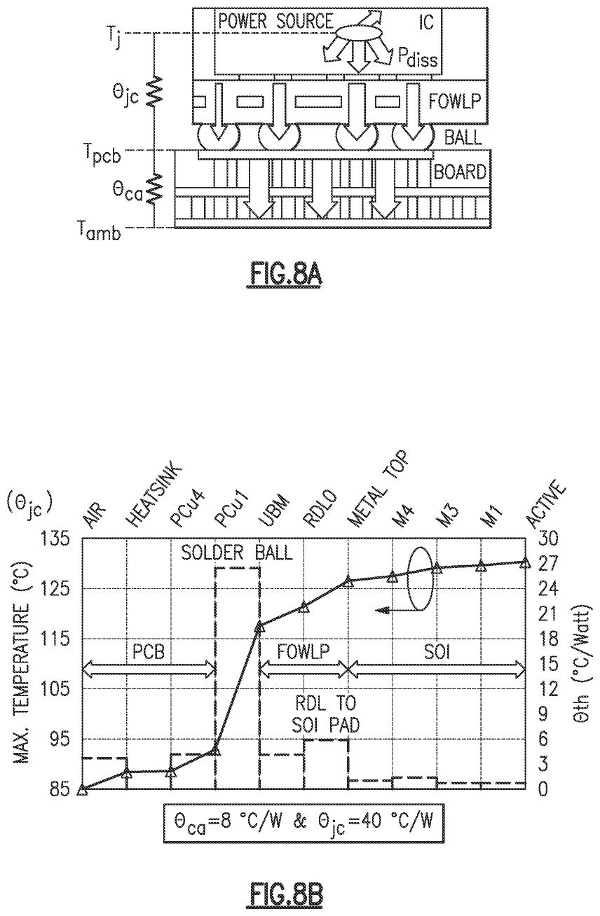

FIG. 8A shows a SOI structure according to an aspect of the present disclosure, and FIG. 8B shows a thermal characteristics depending on locations of the SOI according to aspects of the present disclosure. The major contributors to thermal resistance (θ_{jc}) may be solder ball and redistribution layer (RDL) to SOI junctions. From FIGS. 8A and 8B, it is required to adapt different temperature slope circuits close to the amplifiers to track the real temperature and to compensate for the temperature effects.

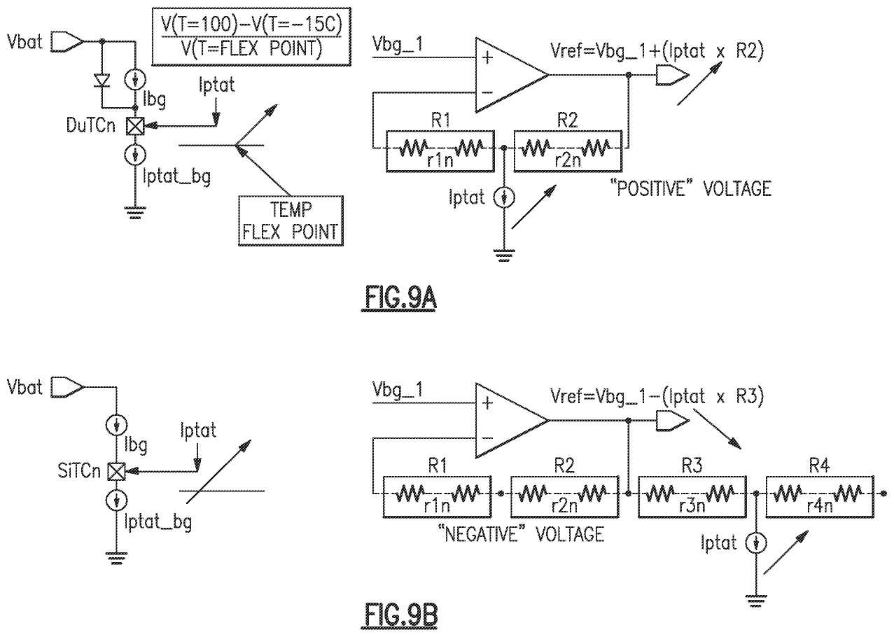

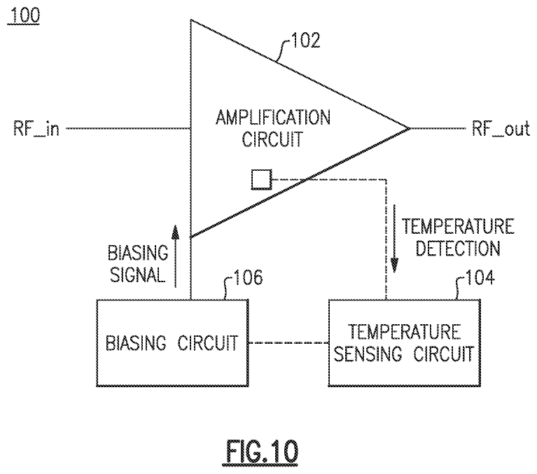

FIGS. 9A and 9B illustrate schematic diagrams of circuits for voltage bias dependent on temperature according to the prior art. The outputs of each circuit according to FIGS. 9A and 9B may respond to the changes of detected temperature. However, such circuit structures still have a huge error for compensating for the effect of the temperature.

Hereinafter, an enhanced temperature compensated amplifier device according to the present disclosure is provided.

The amplifier device according to the present disclosure includes a signal amplifier and a temperature sensing circuit, and at least one biasing circuit. The amplifier device may be one of a power amplifier and a low noise amplifier.

The signal amplifier is configured to amplify a radio frequency signal when powered by a supply voltage and biased by a biasing signal. The temperature sensing circuit is configured to sense a temperature at a certain position of the amplifier.

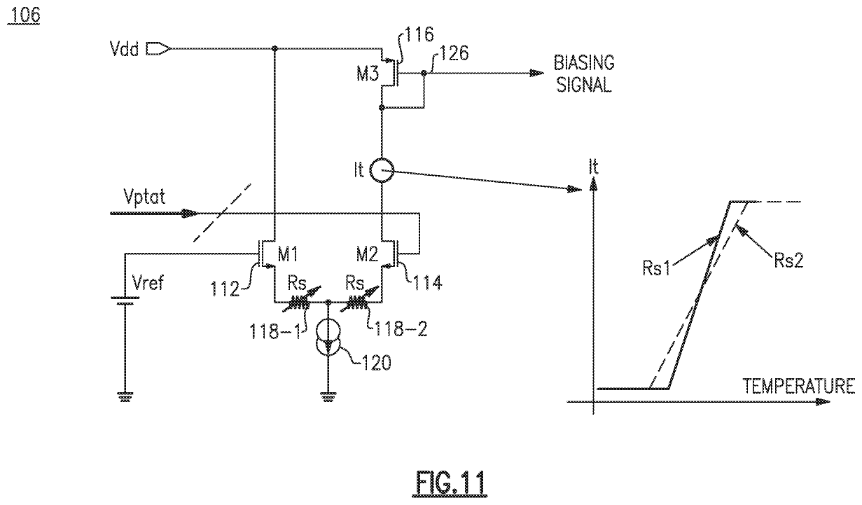

FIG. 10 is a schematic diagram of an amplifier assembly 100 according to an embodiment of the present disclosure. The amplifier assembly 100 may be one of a power amplifier as shown in FIG. 4, or a low noise amplifier (LNA) as shown in FIG. 7, for example. As shown in FIG. 10, the amplifier assembly 100 includes an amplification circuit 102, a temperature sensing circuit 104, and at least one biasing circuit 106.

The amplification circuit 102 may be configured to amplify a radio frequency signal when biased by a biasing signal. Furthermore, the amplification circuit 102 may operate when powered by a supply voltage. The radio frequency signal is received via input node (RF_in), and amplified by the amplification circuit 102 including an amplifier transistor, for example, bipolar junction transistor (BJT) or field effect transistor (FET), and the amplified signal may be output through the output node (RF_out).

The temperature sensing circuit 104 is configured to sense a temperature at a certain position of the amplification circuit 102. The temperature sensing circuit 104 may be disposed on the amplification circuit 102 so that the temperature sensing circuit 104 detects temperature on a particular surface of the amplification circuit 102. According to an embodiment, the temperature sensing circuit 104 may include one or more diodes that are configured to generate different current values depending on the detected temperature. Thus, the temperature sensing circuit 104 may collect one or more temperature values for a single amplification circuit 102.

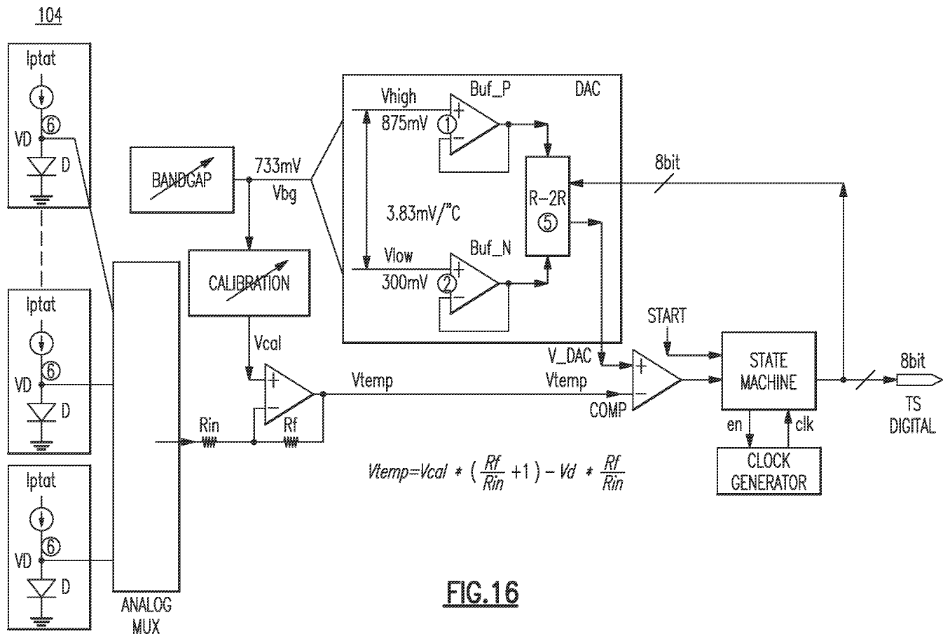

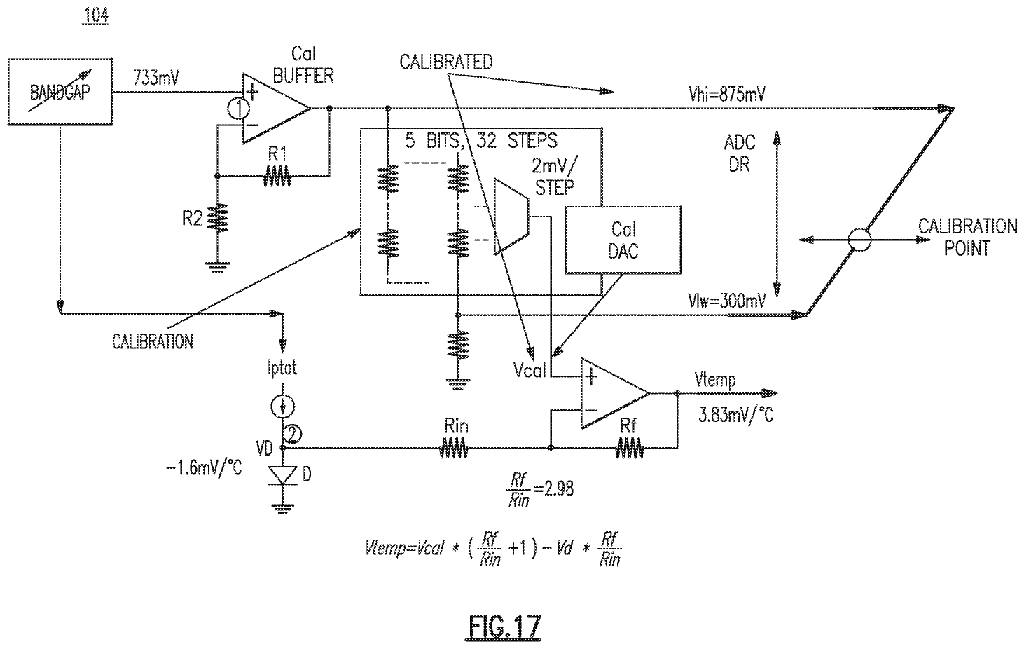

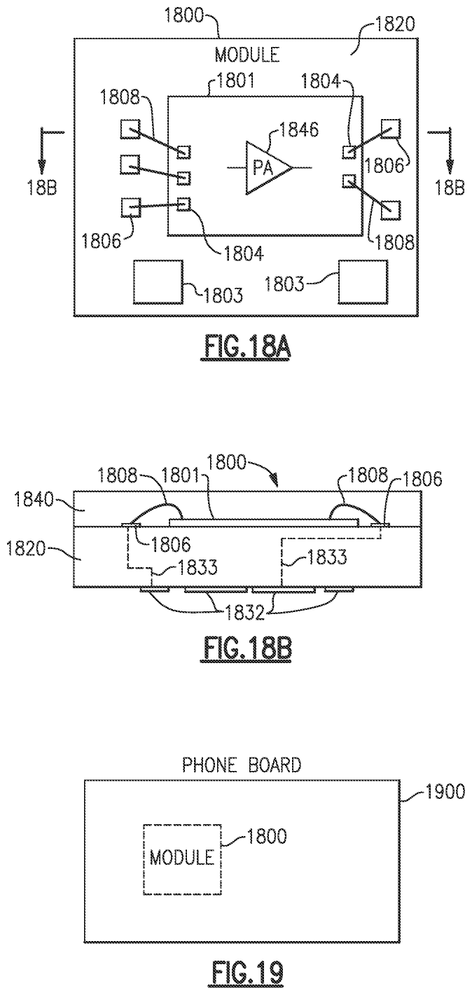

A more detailed structure of the temperature sensing circuit 104 that is further configured to perform a calibration on the detected temperature is provided in FIGS. 17 and 18.

The biasing circuit 106 is configured to generate the biasing signal with a temperature gradient dependent on the sensed temperature. The temperature gradient may be a differential value of biasing signal depending on temperature. As the temperature goes higher, the RF performance, such as gain, of the amplifier assembly will be degraded more rapidly. The temperature gradient may be adjusted based on the absolute value of the sensed temperature, and the biasing signal may be generated depending on the adjusted temperature gradient. According to an embodiment of the present disclosure, the temperature gradient may be defined per preconfigured temperature ranges. For example, a temperature gradient K₁ may correspond to a first temperature range, and a temperature gradient K₂ may correspond to a second temperature range. According to an embodiment of the present disclosure, higher temperature ranges may be configured with a higher temperature gradient. Such a relation between the temperature range and the temperature gradient may be configured in a temperature profile.

A more detailed structure of the biasing circuit 106 will now be described with FIG. 11.

FIG. 11 is a schematic diagram of the biasing circuit 106 according to an embodiment of the present disclosure. Depending on the embodiment, at least one biasing circuit 106 (for example, 1, 2, 3 or 4 biasing circuits) may be provided to an amplifier assembly 100.

As shown in FIG. 11, the biasing circuit 106 may include a first transistor 112, a second transistor 114, and a third transistor 116. At least one of the first transistor 112, the second transistor 114, and the third transistor 116 may be a field effect transistor (FET). The biasing circuit 106 may include slope resistors 118-1, 118-2 connected to the first transistor 112 and the second transistor 114, respectively. The resistance values of the slope resistors 118-1, 118-2 may be identical. The biasing circuit 106 may further include a current source 120 connected to the first transistor 112 and the second transistor 114 such to induce a current proportional to the sensed temperature flowing through the first transistor 112 and the second transistor 114. More specifically, the sum of the currents flowing through the first transistor 112 and the second transistor 114 respectively is the current proportional to the sensed temperature.

The first transistor 112 may be configured to be biased by a reference voltage. The reference voltage may provide a DC voltage. The first transistor 112 may have a gate which is configured to receive the reference voltage. Further, the first transistor 112 may include a drain configured to be provided with a supply voltage. In this embodiment, the first transistor 112 may be an-type FET. The first transistor 112 may further include a source connected to the (first) slope resistor 118-1. The current flowing through the first transistor 112 may go into a current source 120 via the slope resistor 118-1. In other words, the first transistor 112 may be connected to the current source 120 via the slope resistor 118-1. The current source 120 may be configured to provide a current proportional to the sensed temperature.

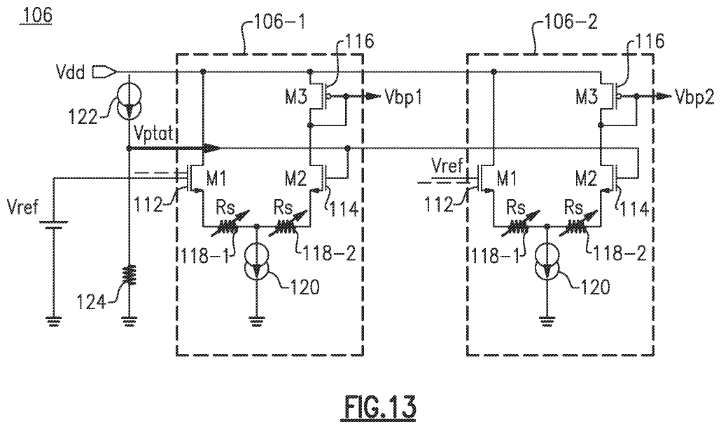

The second transistor 114 may be configured to be biased by an input voltage proportional to the sensed temperature. The second transistor 114 may have a gate biased by the input voltage. According to an embodiment of the present disclosure, the input voltage may be generated by using a current source 122 that provides a current proportional to the sensed temperature and a bias resistor 124, as shown in FIG. 13.

According to an embodiment, the second transistor 114 may be a n-type FET. The second transistor 114 may include a drain connected to the third transistor 116. According to an embodiment, the drain of the second transistor 114 may be connected to the drain of the third transistor 116 which is connected to a gate of the third transistor 116, e.g. an output 126 of the biasing circuit 106.

The second transistor 114 may include a source connected to the current source 120 via the (second) slope resistor 118-2. Thus, the current flowing through the second transistor 114 may go into the current source 120 via the slope resistor 118-2. The voltage at the source of the second transistor 116 may be controlled by the resistance value of the slope resistor 118-2.

The third transistor 116 may be configured to provide the biasing signal based on a control current (It) flowing through the second transistor 114. The control current (It) may flow through the second transistor 114 and the third transistor 116. The third transistor 116 may include a drain connected to the second transistor 114, a source connected to the power supply, and a gate connected to the output of the biasing circuit 106. The gate and the drain of the third transistor 116 may be connected to each other.

According to an embodiment, the biasing circuit 106 may be configured to generate the biasing signal further based on a modulation type of the radio frequency signal. More specifically, the biasing circuit 106 may further include a controller (not shown) configured to adjust the biasing signal, and the controller may adjust the biasing signal based on the modulation type of the radio frequency signal. The modulation type of the radio frequency signal may be a modulation order or modulation bandwidth of the radio frequency. The biasing signal may be adjusted based on a number of resource blocks (RBs) included in a single carrier. According to this embodiment, when the modulation bandwidth of the radio frequency is not relatively high, then the biasing circuit 106 may reduce the amplitude of the biasing signal, because degraded gain of the amplifier device has less impact on the performance of the amplifier assembly 100 in case of low modulation bandwidth.

As described above, the amplifier assembly 100 may include at least one biasing circuit 106 (for example, 1, 2, 3, or 4 biasing circuits). In case of a plurality of biasing circuits, the amplifier assembly 100 may further include a controller (for example, a multiplexer) configured to select one of the plurality of biasing circuits based on a temperature profile describing a behavior of the amplifier assembly 100 in response to temperature. The difference between two different biasing circuits is the resistance values of the slope resistors which determine the temperature gradient. In this embodiment, the amplifier assembly 100 may further comprise a trimming circuit configured to control a level of the biasing signal. That is, the trimming circuit may be configured to adjust the DC level of the biasing signal. The trimming circuit may include a plurality of FETs biased by the selected biasing signal by the controller, e.g., multiplexer. Each of the FETs may be configured to be turned on or off by a respective switch connected to the drain of the respective FETs.

According to an embodiment, the biasing circuit 106 may include a digital decoder (not shown) configured to adjust resistance values of the slope resistors 118-1, 118-2. The resistance values of the slope resistors 118-1, 118-2 may be adjusted according to the sensed temperature based on a temperature profile describing the behavior of the amplifier device in response to temperature. The sensed temperature may be taken into account through the current source 120 which is configured to provide the current proportional to the sensed temperature. In this example, the amplifier assembly 100 may include one biasing circuit 106.

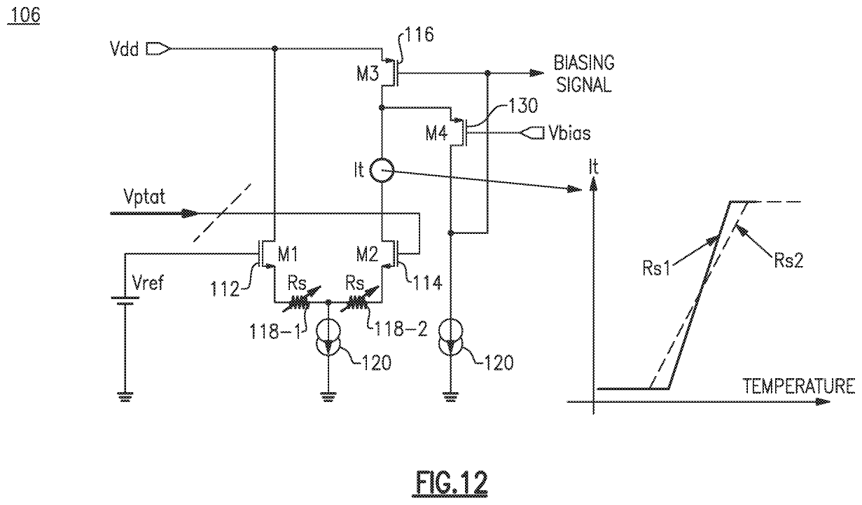

According to an embodiment, the biasing circuit 106 may include a fourth transistor configured to stabilize the control current (It) flowing through the second transistor 114. The arrangement of the fourth transistor is illustrated in FIG. 12 in detail. In particular, in case of a low voltage supply, the fourth transistor may take a role to stabilize the control current (It) flowing through the second transistor 114. In this embodiment, the gate of the third transistor 116, e.g., the output of the biasing circuit 106, may be connected to a drain of the fourth transistor, instead of the drain of the third transistor 116.

As shown in FIG. 11, two different slopes Rs1, Rs2 of the control current (It) flowing through the second transistor 114 versus temperature may be generated by adjusting the values of resistance of the slope resistors 118-1, 118-2.

FIG. 12 is a schematic diagram of the biasing circuit 106 according to an embodiment of the present disclosure.

As shown in FIG. 12, the biasing circuit 106 may further include a fourth transistor 130. The fourth transistor 130 may be a p-type FET. The fourth transistor 130 may include a gate configured to be biased by a bias voltage. The bias voltage may be a DC voltage. The fourth transistor 130 may include a source connected to a drain of the third transistor 116. The fourth transistor 130 may include a drain connected to the gate of the third transistor 116, that is configured to output the biasing signal. The drain of the fourth transistor 130 may be connected to a current source 120 configured to provide a current proportional to the sensed temperature.

As shown in FIG. 12, two different slopes Rs1, Rs2 of the control current (It) flowing through the second transistor 114 versus temperature may be generated by adjusting the values of resistance of the slope resistors 118-1, 118-2.

FIG. 13 is a schematic diagram of a plurality of the biasing circuits 106-1, 106-2 according to an embodiment of the present disclosure.

According to an embodiment of the present disclosure, the amplifier assembly 100 may include a plurality of the biasing circuits 106-1, 106-2. Each of the biasing circuits 106-1, 106-2 may have different temperature gradients. That is, each of the biasing circuits 106-1, 2 may have slope resistors with different resistance values from each other. The amplifier assembly 100 may further include a controller (for example, a multiplexer) configured to select one of the plurality of biasing circuits 106-1, 106-2. The controller may be configured to select one of the biasing circuits based on a temperature profile describing a behavior of the amplifier assembly 100 in response to temperature. However, the number of biasing circuits 106-1, 106-2 is not limited thereto.

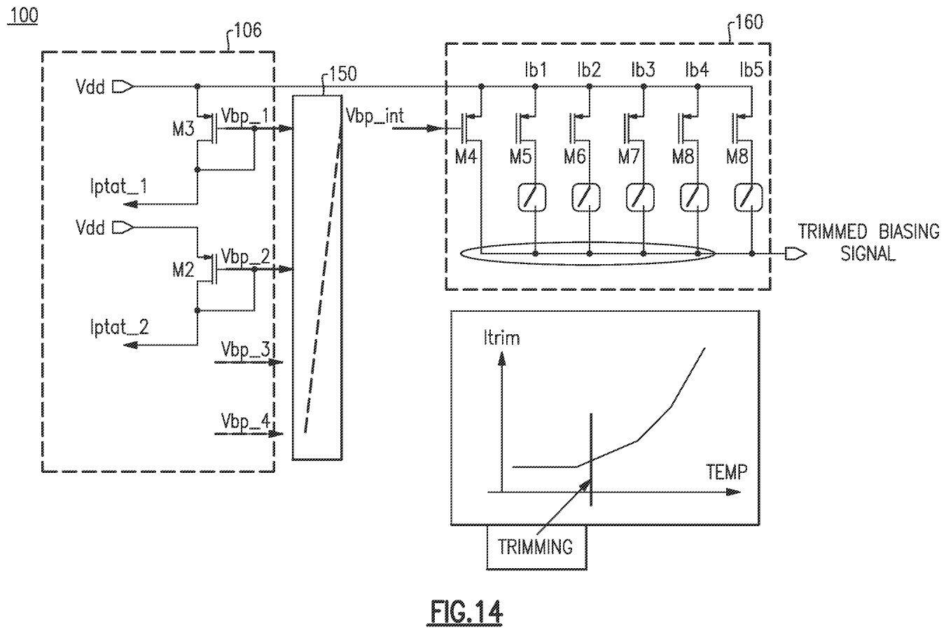

FIG. 14 is a schematic diagram of an amplifier assembly 100 including a plurality of biasing circuits 106, a multiplexer 150 and a trimming circuit 160 according to an embodiment of the present disclosure.

As shown in FIG. 14, the multiplexer 150 may be configured to select one of the plurality of biasing signals output by the biasing circuits 106. The multiplexer 150 may be configured to select one of the biasing signals based on the temperature profile according to the sensed temperature. Each of the biasing signals may have different temperature gradients.

The amplifier assembly 100 may further comprise the trimming circuit 160 configured to control the level of the selected biasing signal. The trimming circuit 160—may be used to trim the required current at room temperature. The trimming circuit 160 may include a plurality of FETs M4-M8 with respective switches. The trimming circuit 160 may include a current mirror stage for adjusting the level of selected biasing signal.

According to an embodiment, the trimmed biasing signal may have a current value which is continuous throughout whole temperature ranges, as shown in FIG. 14.

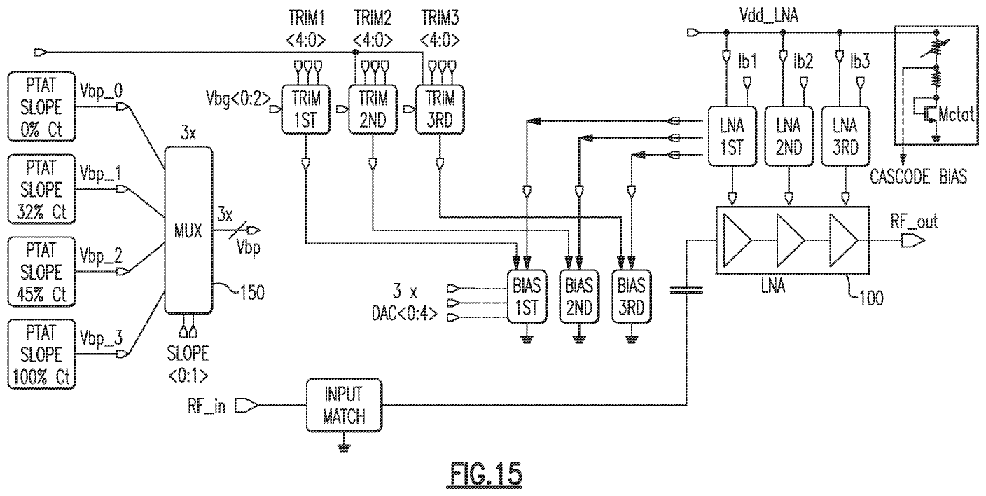

FIG. 15 is a schematic diagram of analog multiplexer 150 according to an embodiment of the present disclosure. As shown in FIG. 15, an amplifier assembly 100, for example, LNA, according to an embodiment may include 3 stages. Each of the stages may be biased by biasing signals depending on the sensed temperature.

FIG. 16 is a schematic diagram of temperature sensing circuit 104 according to an embodiment of the present disclosure. As shown in FIG. 16, multiple points on a die may be monitored using a plurality of diodes.

FIG. 17 is a schematic diagram of temperature sensing circuit 104 including a calibration circuit according to an embodiment of the present disclosure. According to an embodiment, the calibration circuit may help the precision of the current generation.

FIG. 18A is a schematic diagram of one embodiment of a packaged module 1800. FIG. 18B is a schematic diagram of a cross-section of the packaged module 1800 of FIG. 18A taken along the lines 18A-18B.

The packaged module 1800 includes an IC or die 1801, surface mount components 1803, wirebonds 1808, a package substrate 1820, and encapsulation structure 1840. The package substrate 1820 includes pads 1806 formed from conductors disposed therein. Additionally, the die 1801 includes pads 1804, and the wirebonds 808 have been used to electrically connect the pads 1804 of the die 1801 to the pads 1806 of the package substrate 1801.

The die 1801 includes a power amplifier 1846, which can be implemented in accordance with any of the embodiments herein.

The packaging substrate 1820 can be configured to receive a plurality of components such as the die 1801 and the surface mount components 1803, which can include, for example, surface mount capacitors and/or inductors.

As shown in FIG. 18B, the packaged module 1800 is shown to include a plurality of contact pads 1832 disposed on the side of the packaged module 1800 opposite the side used to mount the die 1801. Configuring the packaged module 1800 in this manner can aid in connecting the packaged module 1800 to a circuit board such as a phone board of a wireless device. The example contact pads 1832 can be configured to provide RF signals, bias signals, power low voltage(s) and/or power high voltage(s) to the die 1801 and/or the surface mount components 1803. As shown in FIG. 18B, the electrical connections between the contact pads 1832 and the die 1801 can be facilitated by connections 1833 through the package substrate 1820. The connections 1833 can represent electrical paths formed through the package substrate 1820, such as connections associated with vias and conductors of a multilayer laminated package substrate.

In some embodiments, the packaged module 1800 can also include one or more packaging structures to, for example, provide protection and/or facilitate handling of the packaged module 1800. Such a packaging structure can include overmold or encapsulation structure 1840 formed over the packaging substrate 1820 and the components and die(s) disposed thereon.

It will be understood that although the packaged module 1800 is described in the context of electrical connections based on wirebonds, one or more features of the present disclosure can also be implemented in other packaging configurations, including, for example, flip-chip configurations.

FIG. 19 is a schematic diagram of one embodiment of a phone board 1900. The phone board 1900 includes the module 1800 shown in FIGS. 18A-18B attached thereto. Although not illustrated in FIG. 19 for clarity, the phone board 1900 can include additional components and structures.

### Applications

Some of the embodiments described above have provided examples in connection with wireless devices or mobile phones. However, the principles and advantages of the embodiments can be used for any other systems or apparatus that have needs for power amplifiers.

Techniques in accordance with the present disclosure can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An amplifier assembly comprising:
an amplification circuit configured to amplify a radio frequency signal when biased by a biasing signal;
a temperature sensing circuit configured to sense a temperature at a certain position of the amplification circuit; and
at least one biasing circuit configured to generate the biasing signal with a temperature gradient dependent on the sensed temperature, the biasing circuit including a first transistor biased by a reference voltage and a second transistor biased by an input voltage proportional to the sensed temperature, the first transistor and the second transistor connected to a current source via respective slope resistors such to induce current proportional to the sensed temperature, the biasing circuit including a third transistor configured to output the biasing signal based on a control current flowing through the second transistor, the temperature gradient of the biasing signal being determined by the respective slope resistors.

2. The amplifier assembly of claim 1 wherein the biasing circuit is configured to generate the biasing signal further based on a modulation type of the radio frequency signal.

3. The amplifier assembly of claim 2 wherein the modulation type of the radio frequency signal is a modulation bandwidth determined based on a number of resource blocks included in a single carrier.

4. The amplifier assembly of claim 3 wherein the biasing circuit is configured to adjust the biasing signal to be weaker for smaller modulation bandwidth of the radio frequency signal.

5. The amplifier assembly of claim 1 wherein the first transistor, the second transistor and the third transistor are field effect transistors (FETs).

6. The amplifier assembly of claim 5 wherein the first transistor is a n-type FET including a gate biased by the reference voltage, a drain supplied with a supply voltage, and a source connected to the current source via the respective slope resistor.

7. The amplifier assembly of claim 5 wherein the second transistor is a n-type FET including a gate biased by the input voltage proportional to the sensed temperature, a drain connected to the third transistor, and a source connected to the current source via the respective slope resistor.

8. The amplifier assembly of claim 5 wherein the third transistor is a p-type FET including a gate configured to output the biasing signal, a drain connected to the second transistor, and a source supplied with a supply voltage.

9. The amplifier assembly of claim 1 wherein the amplifier assembly includes a plurality of biasing circuits, each of which has different resistance values of the respective slope resistors.

10. The amplifier assembly of claim 9 wherein the amplifier assembly further includes a multiplexer configured to select one of the plurality of biasing circuits based on a temperature profile describing a behavior of the amplifier assembly in response to temperature.

11. The amplifier assembly of claim 10 wherein the amplifier assembly further includes a trimming circuit configured to adjust a level of the biasing signal.

12. The amplifier assembly of claim 1 wherein the biasing circuit is configured to control resistance values of the respective slope resistors according to the sensed temperature based on a temperature profile describing a behavior of the amplifier assembly in response to temperature.

13. The amplifier assembly of claim 12 wherein the biasing circuit is configured to adjust resistance values of the respective slope resistors using a digital decoder.

14. The amplifier assembly of claim 8 wherein the biasing circuit includes a fourth transistor configured to stabilize the control current flowing through the second transistor.

15. The amplifier assembly of claim 14 wherein the fourth transistor is a p-type transistor including a gate biased by a bias voltage, a source connected to the drain of the third transistor, and a drain connected to the gate of the third transistor.

16. The amplifier assembly of claim 1 wherein the amplifier device is one of power amplifier and a low noise amplifier.

17. A radio frequency module comprising:
a packaging board configured to receive a plurality of components;
an amplifier assembly implemented on the packaging board, the amplifier assembly comprising: an amplification circuit configured to amplify a radio frequency signal when biased by a biasing signal; a temperature sensing circuit configured to sense a temperature at a certain position of the amplification circuit; and at least one biasing circuit configured to generate the biasing signal with a temperature gradient dependent on the sensed temperature, the biasing circuit including a first transistor biased by a reference voltage and a second transistor biased by an input voltage proportional to the sensed temperature, the first transistor and the second transistor connected to a current source via respective slope resistors such to induce current proportional to the sensed temperature, the biasing circuit including a third transistor configured to output the biasing signal based on a control current flowing through the second transistor, the temperature gradient of the biasing signal being determined by the respective slope resistors.

18. The radio frequency module of claim 17 wherein the biasing circuit is configured to generate the biasing signal further based on a modulation type of the radio frequency signal, and wherein the modulation type of the radio frequency signal is a modulation bandwidth determined based on a number of resource blocks included in a single carrier.

19. The radio frequency module of claim 18 wherein the biasing circuit is configured to adjust the biasing signal to be weaker for smaller modulation bandwidth of the radio frequency signal.

20. The radio frequency module of claim 17 wherein the first transistor, the second transistor and the third transistor are field effect transistors (FETs), wherein the first transistor is a n-type FET including a gate biased by the reference voltage, a drain supplied with a supply voltage, and a source connected to the current source via the respective slope resistor, wherein the second transistor is a n-type FET including a gate biased by the input voltage proportional to the sensed temperature, a drain connected to the third transistor, and a source connected to the current source via the respective resistor, and wherein the third transistor is a p-type FET including a gate configured to output the biasing signal, a drain connected to the second transistor, and a source supplied with a supply voltage.
